(19) United States
(12) Patent Application Publication
(10) Pub. No.: US 2025/0012287 A1
(43) Pub. Date: Jan. 9, 2025

(54) Multi Fan Assembly

(71) Applicant: Purple Cloud Development Pte. Ltd., Singapore (SG)

(72) Inventors: Shiman Xu, Singapore (SG); JIASHENG LAI, Singapore (SG)

(21) Appl. No.: 18/761,450

(22) Filed: Jul. 2, 2024

(30) Foreign Application Priority Data
Jul. 4, 2023 (CN) 202321739909.X

(51) Int. Cl. F04D 25/16; F04D 19/00; F04D 29/52; H05K 7/20

(52) U.S. Cl. CPC F04D 25/166; F04D 19/002; F04D 29/522; H05K 7/20172

(57) ABSTRACT

A multi fan assembly may include a multi fan mount rack and a plurality of fan modules. The multi fan mount rack includes a housing and a mount bracket fixedly disposed to the housing. The mount bracket and housing define a mount space therewithin. Each plurality of fan modules includes a fan frame and a fan assembly rotatably disposed within the fan frame. The fan frame comprises at least two interlocking members, each, respectively disposed protruding from a top plane of the fan frame. The at least two interlocking members is configured to lock each plurality of fan modules to the multi fan mount rack within the mount space, wherein each plurality of fan modules is locked to the multi fan mount rack via a pushing force.

### RELATED APPLICATIONS

This US application claims the benefit of priority to China application no. 202321739909.X, filed on Jul. 4, 2023, of which is incorporated herein by reference in its entirety.

### TECHNICAL FIELD

The present disclosure relates to heat-transfer components and assemblies, and more particularly, but not limited to, multi fan assemblies.

### BACKGROUND OF THE INVENTION

With increasing processing speed and performance of electronic devices, the amount of heat generated during operation of an electronic device has increased. The heat generation increases the temperature of the electronic device and, if the heat cannot be dissipated effectively, the reliability and performance of the electronic device is reduced. To prevent overheating of an electronic device, cooling apparatuses such as fans are used to efficiently dissipate the heat generated by the electronic device and, thereby ensure the standard operation of the electronic device.

In the case of multi fan assemblies, one side of each fan may be individually assembled to a multi fan rack using fasteners. For safety, individual fan guards may also be assembled to the rack, covering each fan. Fan power cables are attached to the fans for connecting to a fan connector. However, with more than one fan being assembled together, vibration of the fan assembly due to use of more than one fan increases. As vibration increases, misalignment may occur, causing vibration noises to increase and fasteners to loosen. Also, with increased vibration, poor connection between the power cables and fan connector may lead to one or more fans to stop rotating. Moreover, multi fan assemblies generally have many parts, making assembly time-consuming, and increasing the risk of lost parts. For multi fan assemblies and pre-assembled multi fan assemblies, having many parts makes maintenance, repair, and parts replacement inconvenient and inefficient.

### SUMMARY OF THE INVENTION

The present disclosure provides a multi fan assembly with decreased parts, simplified assembly, and increased fan mounting elements for decreased vibration.

In some aspects, the techniques described herein relate to a multi fan assembly, including a multi fan mount rack and a plurality of fan modules. The multi fan mount rack includes a housing and a mount bracket. The mount bracket is fixedly disposed to a perimeter edge of the housing, wherein the mount bracket and housing define a mount space therewithin. The mount bracket includes a plurality of mount openings. Each plurality of mount openings is in communication with the mount space. Each plurality of fan modules includes a fan frame and a fan assembly. The fan assembly is rotatably disposed within the fan frame. The fan frame includes at least two interlocking members. Each at least two interlocking members is respectively disposed protruding from a top plane of the fan frame. The at least two interlocking members is configured to lock each plurality of fan modules to the multi fan mount rack through each plurality of mount openings and within the mount space, wherein each plurality of fan modules is locked to the multi fan mount rack via a pushing force.

In some aspects, the techniques described herein relate to a multi fan assembly, wherein the multi fan mount rack further includes a base mount, and wherein the housing includes a base and a plurality of walls. The plurality of walls is perpendicularly coupled to the base at perimeter edges of the base. The base mount is disposed abutting the base within the mount space and surrounded by the plurality of walls. The base mount includes a plurality of mount bases. Each plurality of mount bases includes one or more positioning pins. The one or more positioning pins is configured to position each plurality of fan modules on each plurality of mount bases.

In some aspects, the techniques described herein relate to a multi fan assembly, wherein each plurality of mount bases further includes a fan connector, and wherein each plurality of fan modules further includes a fan plug. The fan connector is laterally disposed protruding from the plurality of mount bases and the fan plug is configured to plug into and electrically couple to the fan connector.

In some aspects, the techniques described herein relate to a multi fan assembly, wherein each one or more positioning pins is respectively disposed on opposing corners of each plurality of mount bases, and wherein the fan frame further includes one or more positioning bores. Each one or more positioning bores is disposed at opposing corners of the fan frame. The one or more positioning pins protrude within the one or more positioning bores to position each plurality of fan modules on each plurality of mount bases.

In some aspects, the techniques described herein relate to a multi fan assembly, wherein each at least two interlocking members includes a deflection element and a locker, and wherein each plurality of mount openings includes at least two cut outs. The locker includes an undercut surface. Each at least two cut outs respectively includes a retaining ledge. The undercut surface abuts the retaining ledge after each plurality of fan modules is locked to the multi fan mount rack via the pushing force.

In some aspects, the techniques described herein relate to a multi fan assembly, wherein the base mount further includes one or more compression members. Each one or more compression members is respectively disposed surrounding each one or more positioning pins. Each one or more compression members respectively includes a restoring force. The restoring force presses against the fan frame to increase a pushing force between the undercut surface and the retaining ledge.

In some aspects, the techniques described herein relate to a multi fan assembly, wherein each plurality of fan modules further includes a guard cover, and wherein the fan assembly includes a hub and a plurality of blades. The guard cover is fixedly disposed to a perimeter edge of the fan frame. The plurality of blades radially extending from the hub.

In some aspects, the techniques described herein relate to a multi fan assembly, wherein the plurality of fan modules includes three plurality of fan modules, and wherein the plurality of mount openings includes three plurality of mount openings.

In some aspects, the techniques described herein relate to a multi fan assembly, wherein each at least two interlocking members is respectively disposed on opposing corner of the fan frame. Each at least two interlocking members is further configured to unlock each plurality of fan modules from the multi fan mount rack via a pinching force.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of multi fan assemblies incorporating aspects of the presently disclosed principles are illustrated by way of example, and not by way of limitation.

FIG. 1A illustrates a perspective view of a multi fan assembly, in accordance with various embodiments of the present disclosure.

FIG. 1B illustrates an exploded view of the multi fan assembly of FIG. 1A, in accordance with various embodiments of the present disclosure.

FIG. 2 illustrates a perspective view of a fan module of the multi fan assembly of FIG. 1A, in accordance with various embodiments of the present disclosure.

FIG. 3 illustrates a perspective view of a fan module and a partial perspective view of a multi fan mount rack of the multi fan assembly of FIG. 1A, in accordance with various embodiments of the present disclosure.

FIG. 4 illustrates a partial perspective view of the multi fan assembly of FIG. 1A, having line A-A′ and line B-B′ cross-sections, in accordance with various embodiments of the present disclosure.

FIG. 5 illustrates a cross-section along line A-A′ of the multi fan assembly of FIG. 4, in accordance with various embodiments of the present disclosure.

FIG. 6 illustrates a cross-section along line B-B′ of the multi fan assembly of FIG. 4, in accordance with various embodiments of the present disclosure.

### DETAILED DESCRIPTION

The following describes various principles related to components and assemblies for electronic devices cooling by way of reference to specific examples of multi fan assemblies, including specific arrangements and examples of multi fan mount racks and fan modules embodying innovative concepts. More particularly, but not exclusively, such innovative principles are described in relation to selected examples of components positioning and connecting the fan modules to the multi fan mount racks and interlocking members locking the fan modules to the multi fan mount racks, and well-known functions or constructions are not described in detail for purposes of succinctness and clarity. Nonetheless, one or more of the disclosed principles can be incorporated in various other embodiments of components positioning and connecting the fan modules to the multi fan mount racks and interlocking members locking the fan modules to the multi fan mount racks to achieve any of a variety of desired outcomes, characteristics, and/or performance criteria.

Thus, multi fan mount racks and fan modules having attributes that are different from those specific examples discussed herein can embody one or more of the innovative principles, and can be used in applications not described herein in detail. Accordingly, embodiments of multi fan mount racks and fan modules not described herein in detail also fall within the scope of this disclosure, as will be appreciated by those of ordinary skill in the relevant art following a review of this disclosure.

Example embodiments as disclosed herein are directed to multi fan assemblies that can be used in cooling systems to dissipate high heat loads. The cooling system may be configured on a chassis, within a chassis, or as part of an electronics system that includes heat producing electronic components to be cooled. The cooling system includes at least one multi fan assembly. The multi fan assembly may be coupled to the chassis via a fastener (e.g., bolts, screws, etc.), transporting air to heat producing electronic components to be cooled and/or to an outside of the chassis or electronics system. The cooling system may further comprise one or more liquid-based cooling loops. The multi fan assemblies may be coupled to the back end of a radiator via a fastener at structural portions of the radiator, transporting air through the radiator to an air plenum or to the outside of the chassis or electronics system.

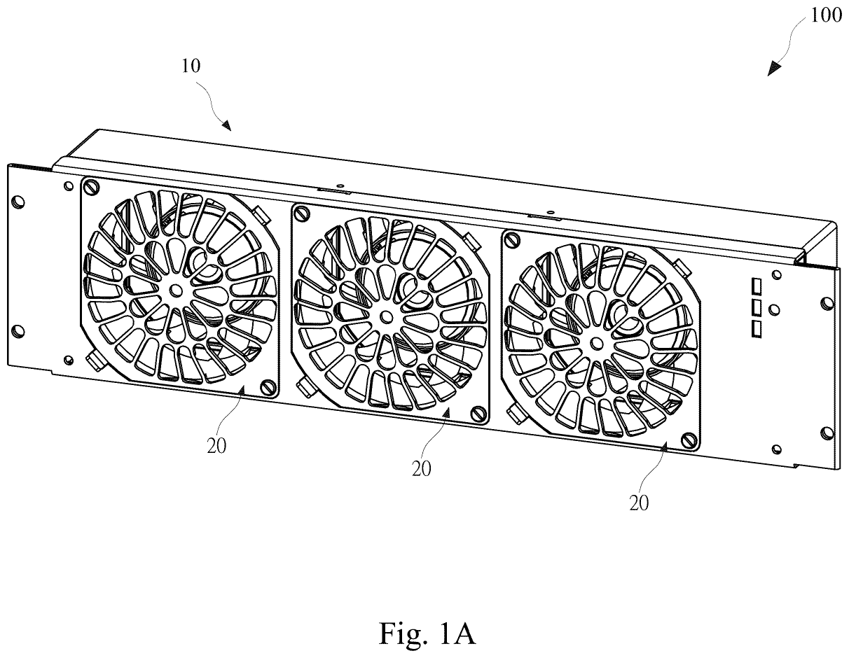

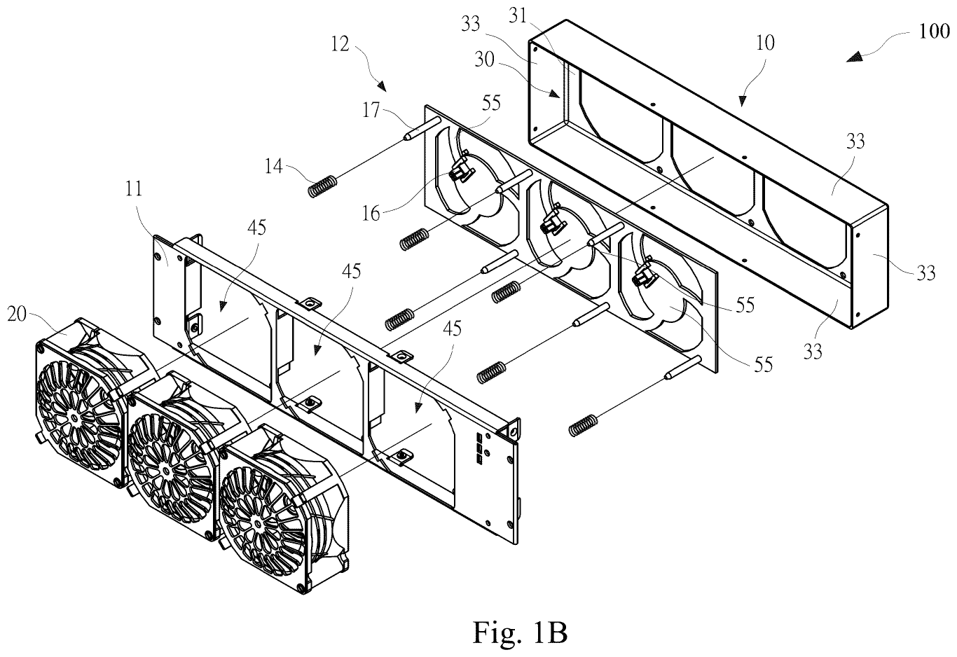

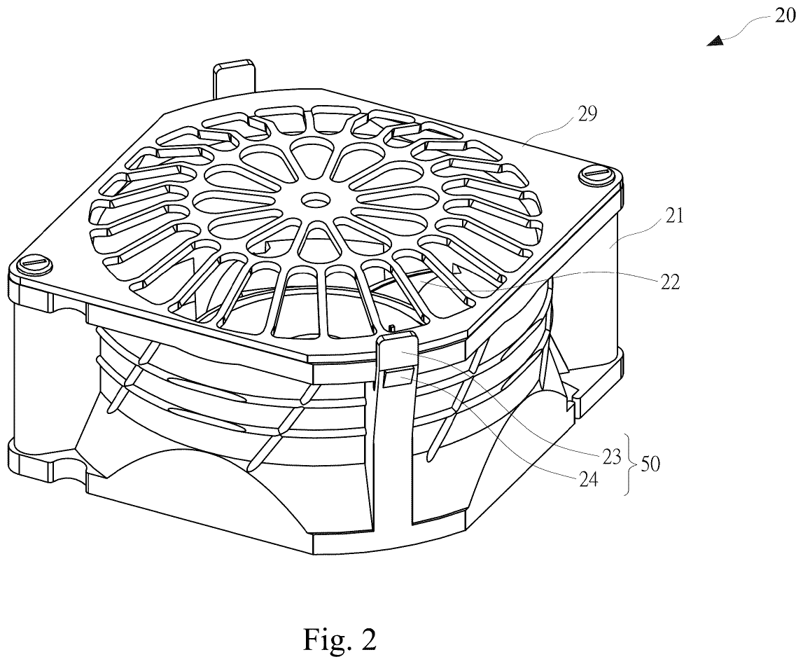

FIGS. 1A to 2 illustrate a multi fan assembly 100, in accordance with various embodiments of the present disclosure. The multi fan assembly 100 includes a multi fan mount rack 10/12/11 and a plurality of fan modules 20. The multi fan mount rack 10/12/11 includes a housing 10 and a mount bracket 11. The mount bracket 11 is fixedly disposed to a perimeter edge of the housing 10, wherein the mount bracket 11 and housing 10 define a mount space 30 therewithin. The mount bracket 11 includes a plurality of mount openings 45. Each plurality of mount openings 45 is in communication with the mount space 30. Each plurality of fan modules 20 includes a fan frame 21 and a fan assembly 28. The fan assembly 28 is rotatably disposed within the fan frame 21. The fan frame 21 includes at least two interlocking members 50. Each at least two interlocking members 50 is respectively disposed protruding from a top plane of the fan frame 21. The at least two interlocking members 50 is configured to lock each plurality of fan modules 20 to the multi fan mount rack 10/12/11 through each plurality of mount openings 45 and within the mount space 30 via a pushing force.

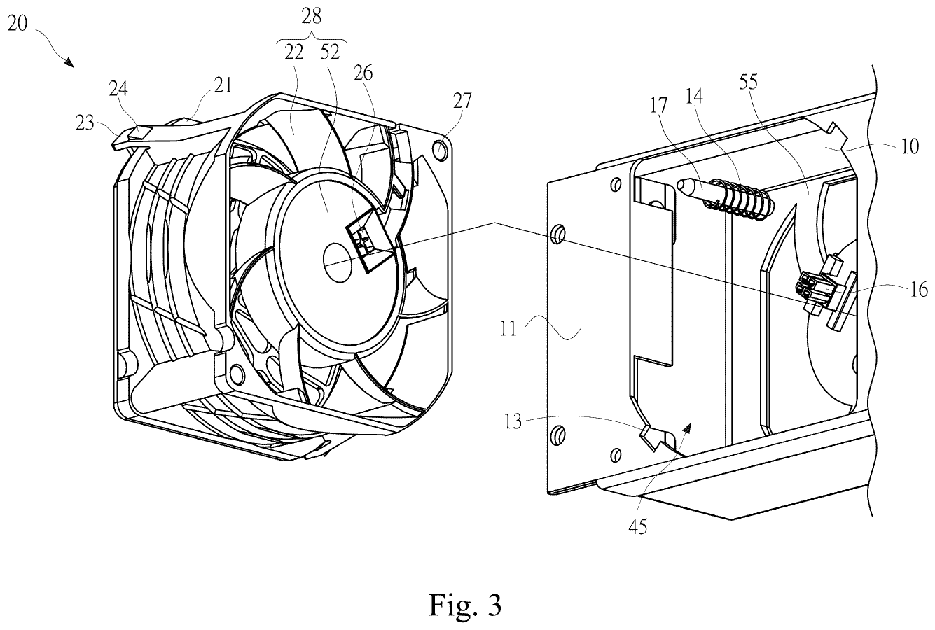

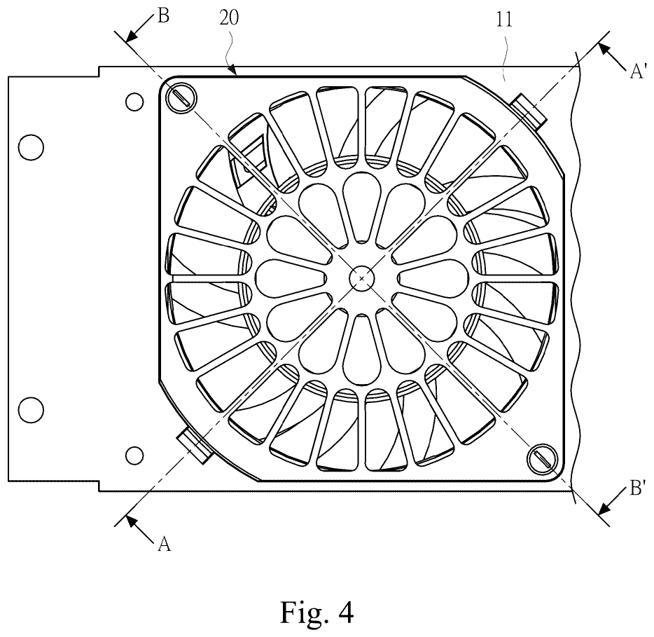

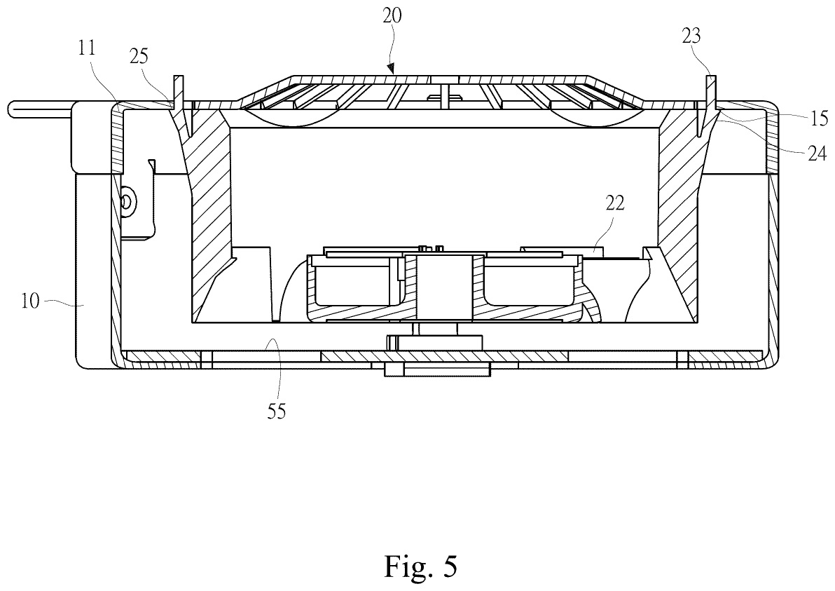

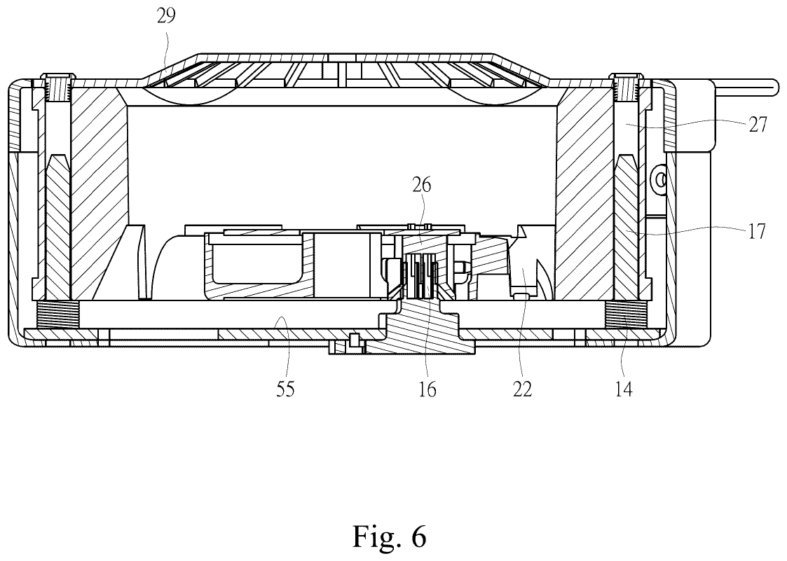

FIGS. 3 to 6 illustrate the multi fan assembly 100, in accordance with various embodiments of the present disclosure. The multi fan mount rack 10/12/11 further includes a base mount 12, and the housing 10 includes a base 31 and a plurality of walls 33. The plurality of walls 33 is perpendicularly coupled to the base 31 at perimeter edges of the base 31, wherein a shape of the mount space 30 can be a cuboid shape. The base mount 12 is disposed abutting the base 31 within the mount space 30 and surrounded by the plurality of walls 33. The base mount 12 includes a plurality of mount bases 55. Each plurality of mount bases 55 corresponds with each plurality of mount openings 45. Each plurality of mount bases 55 includes one or more positioning pins 17. The one or more positioning pins 17 is configured to position each plurality of fan modules 20 on each plurality of mount bases 55.

In some embodiments, each plurality of fan modules 20 further includes a guard cover 29, and the fan assembly 28 includes a hub 52 and a plurality of blades 22. The guard cover 29 is fixedly disposed to a perimeter edge of the fan frame 21 and the plurality of blades 22 radially extending from the hub 52.

In some embodiments, each plurality of mount bases 55 further includes a fan connector 16, and each plurality of fan modules 20 further includes a fan plug 26. The fan connector 16 is laterally disposed protruding from the plurality of mount bases 55 and the fan plug 26 is configured to plug into and electrically couple to the fan connector 16.

In some embodiments, each plurality of mount bases 55 further includes a fan connector 16, and each plurality of fan modules 20 further includes a fan plug 26. The fan plug 26 is laterally disposed protruding from the plurality of fan modules 20 and the fan connector 16 is configured to plug into and electrically couple to the fan plug 26.

In some embodiments, each one or more positioning pins 17 is respectively disposed on opposing corners of each plurality of mount bases 55, and the fan frame 21 further includes one or more positioning bores 27. Each one or more positioning bores 27 is disposed at opposing corners of the fan frame 21. The one or more positioning pins 17 protrude within the one or more positioning bores 27 to position each plurality of fan modules 20 on each plurality of mount bases 55.

In some embodiments, the fan frame (not shown) further includes one or more positioning fan frame pins (not shown) and each plurality of mount bases (not shown) further includes one or more positioning mount bores (not shown). The one or more positioning fan frame pins protrude within the one or more positioning mount bores to position each plurality of fan modules on each plurality of mount bases.

In some embodiments, each at least two interlocking members 50 includes a deflection element 23 and a locker 24, and each plurality of mount openings 45 includes at least two cut outs 13. The locker 24 includes an undercut surface 25. Each at least two cut outs 13 respectively includes a retaining ledge 15. The undercut surface 25 abuts the retaining ledge 15 after each plurality of fan modules 20 is locked to the multi fan mount rack 10/12/11 via the pushing force.

In some embodiments, the base mount 12 further includes one or more compression members 14. Each one or more compression members 14 is respectively disposed surrounding each one or more positioning pins 17. Each one or more compression members 14 respectively includes a restoring force. The restoring force presses against the fan frame 21 to increase a pushing force between the undercut surface 25 and the retaining ledge 15 when the plurality of fan modules 20 is locked to the multi fan mount rack 10/12/11. The one or more compression members 14 can include a compression spring. One end of each one or more compression members 14, disposed surrounding each one or more positioning pins 17, can be coupled to the base mount 12.

When the plurality of fan modules 20 is mounted to the multi fan mount rack 10/12/11 through each plurality of mount openings 45, the one or more positioning bores 27 is required to receive the one or more positioning pins 17 for downward movement of the plurality of fan modules 20 into the mount space 30. When the one or more positioning bores 27 is aligned with the one or more positioning pins 17, the fan plug 26 is aligned with the fan connector 16. Thus, when the plurality of fan modules 20 is pushed into the mount space 30, the fan plug 26 is accurately plugged into the fan connector 16. The one or more positioning pins 17 protruding within the one or more positioning bores 27, the fan plug 26 plugged into the fan connector 16, and the tight fit of the restoring force pressing against the fan frame 21 to increase the pushing force between the undercut surface 25 and the retaining ledge 15, prevent vibration of the plurality of fan modules 20 mounted to the multi fan mount rack 10/12/11.

In some embodiments, the plurality of fan modules 20 includes three plurality of fan modules 20, and the plurality of mount openings 45 includes three plurality of mount openings 45. In some embodiments, the plurality of fan modules includes two plurality of fan modules, and the plurality of mount openings includes two plurality of mount openings (not shown). In some embodiments, the plurality of fan modules includes four plurality of fan modules, and the plurality of mount openings includes four plurality of mount openings (not shown).

In some embodiments, each at least two interlocking members 50 is respectively disposed on opposing corner of the fan frame 21. Each at least two interlocking members 50 is further configured to unlock each plurality of fan modules 20 from the multi fan mount rack 10/12/11 via a pinching force.

When the deflection element 23 is pinched inward toward a center of the fan frame 21, the deflection element 23 is deformed, moving the locker 24 and releasing the undercut surface 25 from the retaining ledge 15. When the undercut surface 25 is released from the retaining ledge 15, the restoring force pushes the fan frame 21 in a vertical direction for removal of the fan plug 26 from the fan connector 16 and removal of the plurality of fan modules 20 from the multi fan mount rack 10/12/11.

Decreased parts, simplified assembly, and increased fan mounting elements provide convenient and efficient assembly of the multi fan assemblies 100 of the embodiments, while also decreasing vibration of the plurality of fan modules 20. The guard cover 29 disposed on the perimeter edge of the fan frame 21 provides a barrier over the plurality of blades 22 to prevent accidental contact with fingers or other components during operation. Thus, maintenance, repair, and parts replacement of each plurality of fan modules 20 is convenient and efficient and opportunity for lost parts is decreased, as multi fan mount rack with only one grill spanning across multiple fan modules require the entire grill to be detached and reattached every time access is required for each individual fan module. The one or more positioning bores 27 aligned with the one or more positioning pins 17, simplify positioning of the plurality of fan modules 20 on the plurality of mount bases 55 by restricting the mounting options to only one downward position movement. Thus, accurate assembly of the plurality of fan modules 20 to the multi fan mount rack 10/12/11 is assured. Moreover, the alignment with the one or more positioning bores 27 and the one or more positioning pins 17 also assures accurate electrical coupling of the fan plug 26 to the fan connector 16. When the plurality of fan modules 20 is pushed into the mount space 30, the fan plug 26 is precisely plugged into the fan connector 16. Thus, multiple cables, wires and connectors are not required, making assembly less time-consuming and more efficient, and faulty and sporadic operation, and prolonged stoppage of the plurality of fan modules 20 due to poor connections because of vibration is lessened. Vibration of the multi fan assembly 100 is decreased as the one or more positioning pins 17 protruding within the one or more positioning bores 27 eliminate horizontal movement of the plurality of fan modules 20. Moreover, the tight fit of the restoring force pressing against the fan frame 21 to increase the pushing force between the undercut surface 25 and the retaining ledge 15 prevents vertical movement of the plurality of fan modules 20. Even furthermore, the fan plug 26 being plugged into the fan connector 16 further prevents horizontal movement and hinders vertical movement of the plurality of fan modules 20. One downward pushing force drives the undercut surface 25 to abut the retaining ledge 15 for locking of the plurality of fan modules 20 to the multi fan mount rack 10/12/11, and one pinching force drives the undercut surface 25 to slide out from the retaining ledge 15 for unlocking of each plurality of fan modules 20 from the multi fan mount rack 10/12/11. Thus, assembly time is simplified and saved, and maintenance, repair, and parts replacement are made convenient and efficient.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

1. A multi fan assembly, comprising:
a multi fan mount rack including a housing and a mount bracket, the mount bracket fixedly disposed to a perimeter edge of the housing, the mount bracket and housing define a mount space therewithin, the mount bracket comprising a plurality of mount openings, each plurality of mount openings in communication with the mount space; and
a plurality of fan modules, each plurality of fan modules includes a fan frame and a fan assembly, the fan assembly rotatably disposed within the fan frame, the fan frame comprising at least two interlocking members, each at least two interlocking members respectively disposed protruding from a top plane of the fan frame, the at least two interlocking members configured to lock each plurality of fan modules to the multi fan mount rack through each plurality of mount openings and within the mount space,
wherein each plurality of fan modules is locked to the multi fan mount rack via a pushing force.

2. The multi fan assembly of claim 1, wherein the multi fan mount rack further includes a base mount, and wherein the housing comprises a base and a plurality of walls, the plurality of walls perpendicularly coupled to the base at perimeter edges of the base, the base mount disposed abutting the base within the mount space and surrounded by the plurality of walls, the base mount comprising a plurality of mount bases, each plurality of mount bases comprises one or more positioning pins, the one or more positioning pins configured to position each plurality of fan modules on each plurality of mount bases.

3. The multi fan assembly of claim 2, wherein each plurality of mount bases further comprises a fan connector, and wherein each plurality of fan modules further includes a fan plug, the fan connector laterally disposed protruding from the plurality of mount bases, the fan plug configured to plug into and electrically couple to the fan connector.

4. The multi fan assembly of claim 2, wherein each one or more positioning pins is respectively disposed on opposing corners of each plurality of mount bases, and wherein the fan frame further comprises one or more positioning bores, each one or more positioning bores disposed at opposing corners of the fan frame, the one or more positioning pins protrude within the one or more positioning bores to position each plurality of fan modules on each plurality of mount bases.

5. The multi fan assembly of claim 4, wherein each at least two interlocking members comprises a deflection element and a locker, the locker comprises an undercut surface, and wherein each plurality of mount openings comprises at least two cut outs, each at least two cut outs respectively comprising a retaining ledge, wherein the undercut surface abuts the retaining ledge after each plurality of fan modules is locked to the multi fan mount rack via the pushing force.

6. The multi fan assembly of claim 5, wherein the base mount further comprises one or more compression members, each one or more compression members respectively disposed surrounding each one or more positioning pins, each one or more compression members respectively comprises a restoring force, wherein the restoring force presses against the fan frame to increase a pushing force between the undercut surface and the retaining ledge.

7. The multi fan assembly of claim 1, wherein each plurality of fan modules further includes a guard cover, and wherein the fan assembly comprises a hub and a plurality of blades, the guard cover fixedly disposed to a perimeter edge of the fan frame, the plurality of blades radially extending from the hub.

8. The multi fan assembly of claim 1, wherein the plurality of fan modules comprises three plurality of fan modules, and wherein the plurality of mount openings comprises three plurality of mount openings.

9. The multi fan assembly of claim 1, wherein each at least two interlocking members is respectively disposed on opposing corner of the fan frame, and wherein each at least two interlocking members is further configured to unlock each plurality of fan modules from the multi fan mount rack via a pinching force.
